(19) United States
(12) Patent Application Publication
(10) Pub. No.: US 2026/0269793 A1
(43) Pub. Date: Sep. 10, 2026

(54) REDUCING DRIVER STAGE FOOTPRINT IN A MULTI-STAGE DIFFERENTIAL POWER AMPLIFIER CIRCUIT

(71) Applicant: Qorvo US, Inc., Greensboro, NC (US)

(72) Inventors: Marcus Granger-Jones, Scotts Valley, CA (US); Nadim Khlat, Ceret (FR); Hwiseob Lee, Cupertino, CA (US); Toshiaki Moriuchi, San Jose, CA (US)

(21) Appl. No.: 19/535,056

(22) Filed: Feb. 10, 2026

Related U.S. Application Data
(60) Provisional application No. 63/767,656, filed on Mar. 6, 2025.

(51) Int. Cl. H03F 3/24; H03F 1/56

(52) U.S. Cl. CPC H03F 3/24; H03F 1/56; H03F 2200/192; H03F 2200/336; H03F 2200/451; H03F 2200/534; H03F 2200/541

(57) ABSTRACT

Reducing a driver stage footprint in a multi-stage differential power amplifier circuit is disclosed. Herein, the driver stage can amplify a radio frequency (RF) signal and output a pair of differential signals that are in quadrature (a.k.a. ±90° out of phase) to each other. The pair of differential signals can be further amplified by one or more output stage power amplifiers, depending on an instantaneous power level of the RF signal, to achieve a higher gain and/or output power. In various embodiments disclosed herein, the driver stage in the multi-stage differential power amplifier circuit can be optimized to include no more than two transformers to help reduce the driver stage footprint compared to a conventional design of the driver stage. As a result, the driver stage can be built on a smaller die to help reduce an overall footprint of the multi-stage differential power amplifier circuit.

### RELATED APPLICATIONS

This application claims the benefit of U.S. provisional patent application serial number 63/767,656, filed on Mar. 6, 2025, the disclosure of which is hereby incorporated herein by reference in its entirety.

### FIELD OF THE DISCLOSURE

The present disclosure is related to reducing a driver stage footprint in a multi-stage differential power amplifier circuit.

### BACKGROUND

Mobile communication devices have become increasingly common in current society for providing wireless communication services. The prevalence of these mobile communication devices is driven in part by the many functions that are now enabled on such devices. Increased processing capabilities in such devices means that mobile communication devices have evolved from being pure communication tools into sophisticated mobile multimedia centers that enable enhanced user experiences.

The redefined user experience requires higher data rates offered by advanced wireless communication technologies such as fifth-generation new-radio (5G-NR). To achieve higher data rates, a mobile communication device is required to amplify a transmission signal to a desired power level to help overcome potential propagation losses and/or interferences. As such, the mobile communication device typically includes a transceiver circuit, a power amplifier circuit, and a power management circuit. Specifically, the transceiver circuit modulates the transmission signal to an intended transmission frequency, the power amplifier circuit amplifies the transmission signal to the desired power level, and the power management circuit supplies an envelope tracking (ET) to the power amplifier circuit. Understandably, to achieve the best possible efficiency and performance, the power management circuit must adapt the ET voltage in accordance with a modulation bandwidth of the transmission signal.

### SUMMARY

Embodiments of the disclosure relate to reducing a driver stage footprint in a multi-stage differential power amplifier circuit. Herein, the driver stage can amplify a radio frequency (RF) signal and output a pair of differential signals that are in quadrature (a.k.a. ±90° out of phase) to each other. The pair of differential signals can be further amplified by one or more output stage power amplifiers, depending on an instantaneous power level of the RF signal, to achieve a higher gain and/or output power. In various embodiments disclosed herein, the driver stage in the multi-stage differential power amplifier circuit can be optimized to include no more than two transformers to help reduce the driver stage footprint compared to a conventional design of the driver stage. As a result, the driver stage can be built on a smaller die to help reduce an overall footprint of the multi-stage differential power amplifier circuit.

In one aspect, a multi-stage differential power amplifier circuit is provided. The multi-stage differential power amplifier circuit includes a driver stage. The driver stage includes at most two transformers. The driver stage is configured to amplify an RF signal and output a first differential signal and a second differential signal in quadrature to the first differential signal. Each of the first differential signal and the second differential signal comprises a respective non-inverting component and a respective inverting component. The multi-stage differential power amplifier circuit also includes a first output stage differential power amplifier. The first output stage differential power amplifier is always activated to further amplify the first differential signal based on a supply voltage. The multi-stage differential power amplifier circuit also includes a second output stage differential power amplifier. The second output stage differential power amplifier is activated only when an instantaneous power level of the RF signal is higher than a first power threshold to further amplify the second differential signal based on the supply voltage. The multi-stage differential power amplifier circuit also includes an output circuit. The output circuit is configured to output the amplified RF signal based on the amplified first differential signal and the amplified second differential signal.

In another aspect, a wireless device is provided. The wireless device includes a multi-stage differential power amplifier circuit. The multi-stage differential power amplifier circuit includes a driver stage. The driver stage includes at most two transformers. The driver stage is configured to amplify an RF signal and output a first differential signal and a second differential signal in quadrature to the first differential signal. Each of the first differential signal and the second differential signal comprises a respective non-inverting component and a respective inverting component. The multi-stage differential power amplifier circuit also includes a first output stage differential power amplifier. The first output stage differential power amplifier is always activated to further amplify the first differential signal based on a supply voltage. The multi-stage differential power amplifier circuit also includes a second output stage differential power amplifier. The second output stage differential power amplifier is activated only when an instantaneous power level of the RF signal is higher than a first power threshold to further amplify the second differential signal based on the supply voltage. The multi-stage differential power amplifier circuit also includes an output circuit. The output circuit is configured to output the amplified RF signal based on the amplified first differential signal and the amplified second differential signal.

In another aspect, a method for reducing an input footprint of a multi-stage differential power amplifier circuit is provided. The method includes amplifying an RF signal and outputting a first differential signal and a second differential signal in quadrature to the first differential signal using a driver stage comprising at most two transformers. Each of the first differential signal and the second differential signal comprises a respective non-inverting component and a respective inverting component. The method also includes always amplifying the first differential signal using a first output stage differential power amplifier. The method also includes amplifying the second differential signal using a second output stage differential power amplifier when an instantaneous power level of the RF signal is higher than a first power threshold. The method also includes outputting the amplified RF signal based on the amplified first differential signal and the amplified second differential signal.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure and, together with the description, serve to explain the principles of the disclosure.

FIG. 1 is a schematic diagram of an exemplary power management circuit wherein a multi-stage differential power amplifier circuit is configured according to embodiments of the present disclosure to reduce the footprint of a driver stage;

FIG. 2 is a graphic diagram illustrating an operating principle of the multi-phase differential power amplifier circuit in FIG. 1;

FIG. 3 is a schematic diagram of an exemplary conventional driver stage that commands a larger footprint;

FIG. 4A is a schematic diagram providing an exemplary illustration of the driver stage in FIG. 1 configured according to an embodiment to reduce the footprint of the conventional driver stage of FIG. 3;

FIG. 4B is a schematic diagram providing an exemplary illustration of the driver stage in FIG. 1 configured according to another embodiment to reduce the footprint of the conventional driver stage of FIG. 3;

FIG. 5 is a schematic diagram providing an exemplary illustration of the driver stage in FIG. 1 configured according to another embodiment to reduce the footprint of the conventional driver stage of FIG. 3;

FIG. 6 is a schematic diagram of an exemplary communication device wherein the power management circuit of FIG. 1 can be provided; and

FIG. 7 is a flowchart of an exemplary process for reducing a driver stage footprint of the multi-stage differential power amplifier circuit in FIG. 1.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term "and/or" includes any and all combinations of one or more of the associated listed items.

It will be understood that when an element such as a layer, region, or substrate is referred to as being "on" or extending "onto" another element, it can be directly on or extend directly onto the other element or intervening elements may also be present. In contrast, when an element is referred to as being "directly on" or extending "directly onto" another element, there are no intervening elements present. Likewise, it will be understood that when an element such as a layer, region, or substrate is referred to as being "over" or extending "over" another element, it can be directly over or extend directly over the other element or intervening elements may also be present. In contrast, when an element is referred to as being "directly over" or extending "directly over" another element, there are no intervening elements present. It will also be understood that when an element is referred to as being "connected" or "coupled" to another element, it can be directly connected or coupled to the other element or intervening elements may be present. In contrast, when an element is referred to as being "directly connected" or "directly coupled" to another element, there are no intervening elements present.

Relative terms such as "below" or "above" or "upper" or "lower" or "horizontal" or "vertical" may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms "a," "an," and "the" are intended to include the plural forms as well, unless the context clearly indicates otherwise. It will be further understood that the terms "comprises," "comprising," "includes," and/or "including" when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to reducing a driver stage footprint in a multi-stage differential power amplifier circuit. Herein, the driver stage can amplify a radio frequency (RF) signal and output a pair of differential signals that are in quadrature (a.k.a. ±90° out of phase) to each other. The pair of differential signals can be further amplified by one or more output stage power amplifiers, depending on an instantaneous power level of the RF signal, to achieve a higher gain and/or output power. In various embodiments disclosed herein, the driver stage in the multi-stage differential power amplifier circuit can be optimized to include no more than two transformers to help reduce the driver stage footprint compared to a conventional design of the driver stage. As a result, the driver stage can be built on a smaller die to help reduce an overall footprint of the multi-stage differential power amplifier circuit.

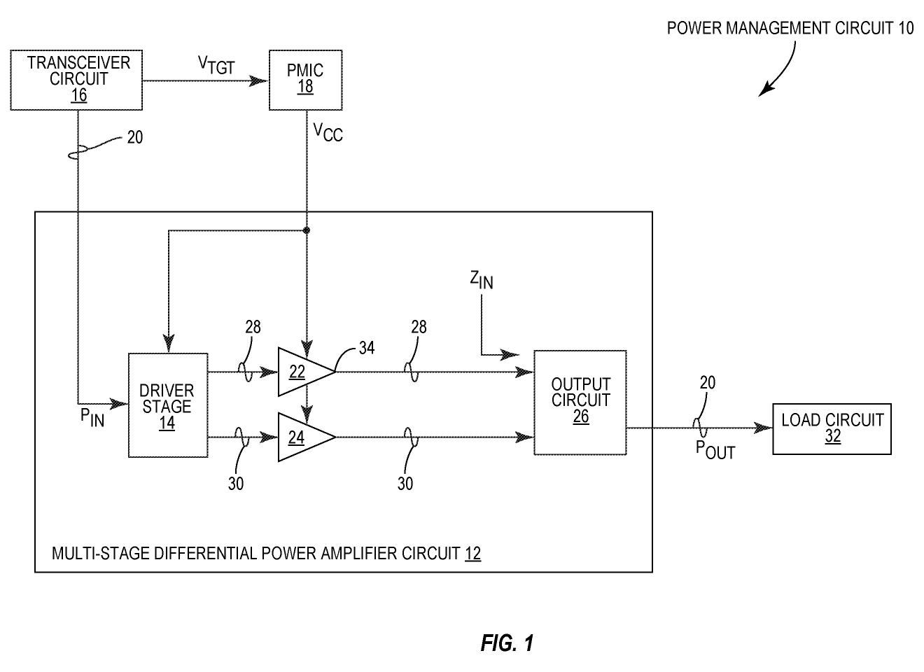

FIG. 1 is a schematic diagram of an exemplary power management circuit 10 wherein a multi-stage differential power amplifier circuit 12 is configured according to embodiments of the present disclosure to reduce the footprint of a driver stage 14. In context of the present disclosure, a multi-stage differential power amplifier circuit refers generally to a power amplifier circuit that includes two or more amplification stages (e.g., driver stage and output stage). In addition, at least one of the amplification stages in the multi-stage differential power amplifier circuit can include a differential power amplifier(s) configured to amplify a differential signal consisting of a pair of opposite-phased (e.g., a 0°-180° differential signal or a 90°-270° differential signal) signals. Moreover, a pair of differential signals can be said to be in quadrature when the pair of differential signals are ±90° out of phase (e.g., a 0°-180° differential signal vs. a 90°-270° differential signal) to each other.

The power management circuit 10 includes a transceiver circuit 16 and a power management integrated circuit (PMIC) 18. The transceiver circuit 16 is configured to generate an RF signal 20 having a time-variant input power P_{IN} and a target voltage V_{TGT} that tracks the time-variant input power P_{IN} of the RF signal 20. The PMIC 18 is configured to generate a supply voltage V_{CC} based on the target voltage V_{TGT}. In one embodiment, the PMIC 18 can generate the supply voltage V_{CC} as an envelope tracking (ET) voltage to track the time-variant input power P_{IN} of the RF signal 20. In another embodiment, the PMIC 18 can generate the supply voltage V_{CC} as an average power tracking (APT) voltage in accordance with an average of the time-variant input power P_{IN} of the RF signal 20.

In addition to the driver stage 14, the multi-stage differential power amplifier circuit 12 also includes a first output stage differential power amplifier 22, a second output stage differential power amplifier 24, and an output circuit 26. The driver stage 14 is configured to amplify the RF signal 20 based on the supply voltage V_{CC} and generate a first differential signal 28 and a second differential signal 30 based on the amplified RF signal 20. The first output stage differential power amplifier 22 is always active to further amplify the first differential signal 28, whereas the second output stage differential power amplifier 24 is conditionally activated to further amplify the second differential signal 30. The output circuit 26 is configured to serve dual purposes. On one hand, the output circuit 26 combines the amplified first differential signal 28 and the amplified second differential signal 30 to thereby output the amplified RF signal 20 to a coupled load circuit 32. On the other hand, the output circuit 26 is configured to manipulate a load impedance Z_{IN} at an output 34 of the first output stage differential power amplifier 22.

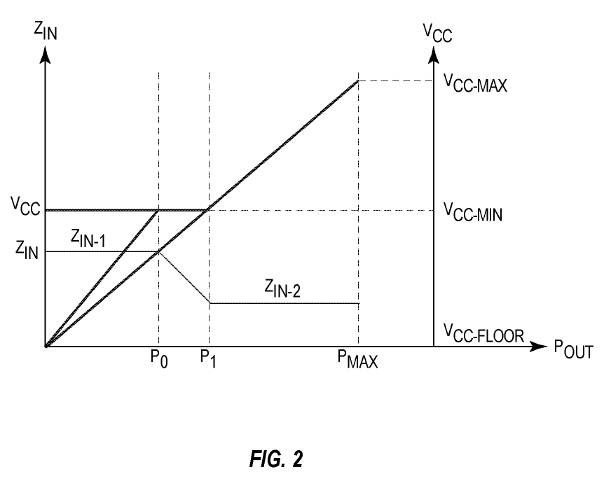

FIG. 2 is a graphic diagram illustrating an operating principle of the multi-stage differential power amplifier circuit 12 in FIG. 1. Common elements between FIGS. 1 and 2 are shown therein with common element numbers and will not be re-described herein.

In an embodiment, the output circuit 26 modulates the load impedance Z_{IN} based on a first power threshold P₀ and a second power threshold P₁. Herein, the second power threshold P₁ is approximately 8 to 10 dBs below a maximum power level P_{MAX} of the RF signal 20 and the first power threshold P₀ is approximately 4 to 6 dBs below the second power threshold P₁.

When the instantaneous power level of the RF signal 20 is lower than or equal to the first power threshold P₀, the output circuit 26 modulates the load impedance Z_{IN} at a first fixed level Z_{IN-1}. When the instantaneous power level of the RF signal 20 is higher than or equal to the second power threshold P₁, the output circuit 26 modulates the load impedance Z_{IN} at a second fixed level Z_{IN-2} (Z_{IN-2} < Z_{IN-1}). When the instantaneous power level of the RF signal 20 is between the first power threshold P₀ and the second power threshold P₁, the output circuit 26 modulates the load impedance Z_{IN} in accordance with the instantaneous power level of the RF signal 20.

In general, modulating the load impedance Z_{IN} can be performed by any passive impedance modulation circuits and the output circuit 26 is just one type of such passive impedance modulation circuits. For a more in-depth description and specific examples in terms of modulating the load impedance Z_{IN} using a passive impedance modulation circuit, please refer to PCT Patent Application Number PCT/US2025/033449, entitled “CONTROLLING A DUAL-AMPLIFIER POWER AMPLIFIER CIRCUIT IN A POWER MANAGEMENT CIRCUIT,” and PCT Patent Application Number PCT/US2025/041493, entitled “REDUCING SUPPLY VOLTAGE RANGE IN A POWER MANAGEMENT CIRCUIT.”

In addition to manipulating the load impedance Z_{IN} at the output 34 of the first output stage differential power amplifier 22, the PMIC 18 is also configured to adapt the supply voltage V_{CC} in accordance with the instantaneous power level of the RF signal 20. Specifically, when the instantaneous power level of the RF signal 20 is lower than or equal to the first power threshold P₀, the PMIC 18 maintains the supply voltage V_{CC} constantly at the minimum voltage level V_{CC-MIN} independent of how the instantaneous power level of the RF signal 20 varies. Herein, the second output stage differential power amplifier 24 is deactivated, whereas the first output stage differential power amplifier 22 is activated to amplify the RF signal 20 (more specifically, the first differential signal 28) based on the supply voltage V_{CC}. As such, the multi-stage differential power amplifier circuit 12 is said to operate without modulation.

When the instantaneous power level of the RF signal 20 is higher than the first power threshold P₀ but lower than or equal to the second power threshold P₁, the first output stage differential power amplifier 22 will operate under full compression and the second output stage differential power amplifier 24 will be activated. As such, the multi-stage differential power amplifier circuit 12 is said to operate based on load modulation. The PMIC 18 maintains the supply voltage V_{CC} at the minimum voltage level V_{CC-MIN}.

When the instantaneous power level of the RF signal 20 becomes higher than the second power threshold P₁, the second output stage differential power amplifier 24 will also operate under full compression. The PMIC 18 will once again generate the supply voltage V_{CC} in accordance with the instantaneous power of the RF signal 20. In this regard, the multi-stage differential power amplifier circuit 12 will return to operating based on supply modulation. In the meantime, the first output stage differential power amplifier 22 and the second output stage differential power amplifier 24 will be biased equally to each deliver one-half (½) of the time-variant output power P_{OUT} and collectively drive the time-variant output power P_{OUT} toward the peak power level P_{MAX}.

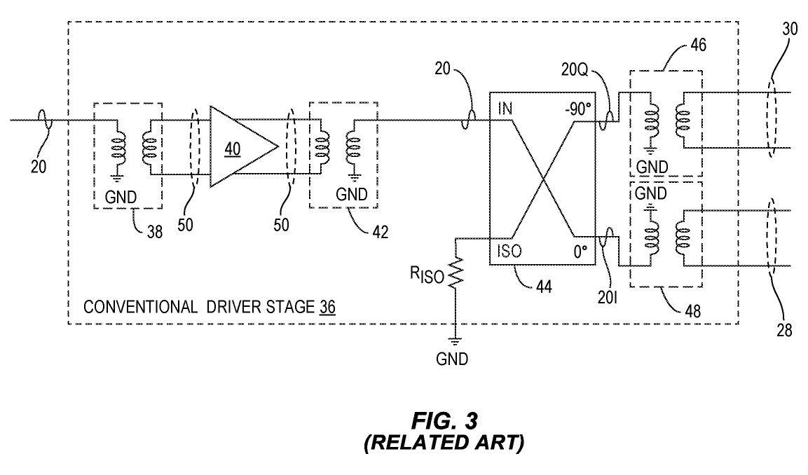

With reference back to FIG. 1, a conventional implementation of the driver stage 14 often demands a larger footprint. In this regard, FIG. 3 is a schematic diagram of an exemplary conventional driver stage 36, which undesirably occupies a larger footprint. Common elements between FIGS. 1 and 3 are shown therein with common element numbers and will not be re-described herein.

Herein, the conventional driver stage 36 includes an input unbalanced-to-balanced transformer 38, a driver stage differential power amplifier 40, a balanced-to-unbalanced transformer 42, a hybrid coupler 44, a quadrature unbalanced-to-balanced transformer 46, and an in-phase unbalanced-to-balanced transformer 48. As shown herein, the hybrid coupler 44 has an input port (denoted as “IN”) coupled to the balanced-to-unbalanced transformer 42 and an isolation port (denoted as “ISO”) coupled to a ground (GND) via an isolation resistor R_{ISO}. The hybrid coupler 44 also includes a quadrature output (denoted as “-90°”) coupled to the quadrature unbalanced-to-balanced transformer 46 and an in-phase output (denoted as “0°”) coupled to the in-phase unbalanced-to-balanced transformer 48.

The input unbalanced-to-balanced transformer 38 converts the RF signal 20 into a differential RF signal 50 to be amplified by the driver stage differential power amplifier 40. The balanced-to-unbalanced transformer 42 converts the amplified differential RF signal 50 back to the RF signal 20 and provides the amplified RF signal 20 to the in-phase input (“IN”) of the hybrid coupler 44. The hybrid coupler 44, in turn, outputs a quadrature signal 20Q and an in-phase signal 20I via the quadrature output (-90°) and the in-phase output (0°), respectively. Subsequently, the in-phase unbalanced-to-balanced transformer 48 converts the in-phase signal 20I into the first differential signal 28 and the quadrature unbalanced-to-balanced transformer 46 converts the quadrature signal 20Q into the second differential signal 30.

Notably, the balanced-to-unbalanced transformer 42, the quadrature unbalanced-to-balanced transformer 46, and the in-phase unbalanced-to-balanced transformer 48 can increase the footprint of the conventional driver stage 36. As such, the technical problem to be solved herein is to reduce the footprint of the conventional driver stage 36 by eliminating some of the transformers employed therein.

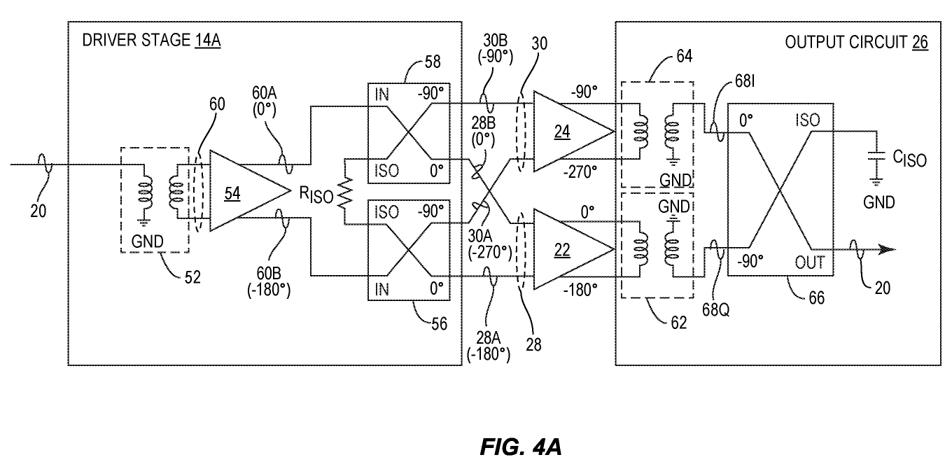

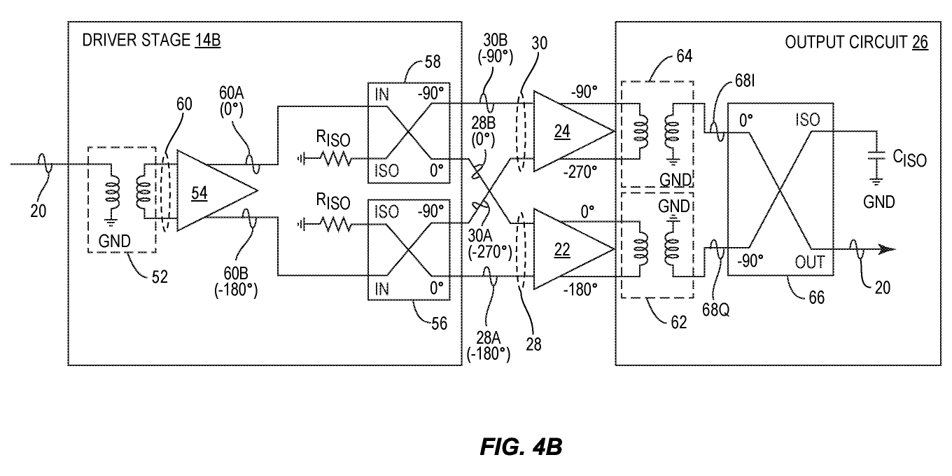

FIG. 4A is a schematic diagram providing an exemplary illustration of a driver stage 14A, which can replace the driver stage 14 in FIG. 1 and configured according to an embodiment to occupy a smaller footprint compared to the conventional driver stage 36 in FIG. 3. Common elements between FIGS. 1 and 4A are shown therein with common element numbers and will not be re-described herein.

Herein, the driver stage 14A includes an unbalanced-to-balanced transformer 52, a driver stage differential power amplifier 54, a first input hybrid coupler 56, and a second input hybrid coupler 58. In an embodiment, the unbalanced-to-balanced transformer 52 is configured to convert the RF signal 20 into a driver stage differential signal 60. As an example, the driver stage differential signal 60 includes a non-inverting driver stage signal 60A associated with a 0° phase and an inverting driver stage signal 60B associated with a -180° phase offset relative to the non-inverting driver stage signal 60A. The driver stage differential power amplifier 54 is configured to amplify both the non- inverting driver stage signal 60A and the inverting driver stage signal 60B in the driver stage differential signal 60.

The first input hybrid coupler 56 and the second input hybrid coupler 58 each includes a respective input port (denoted as “IN”), a respective isolation port (denoted as “ISO”), a respective quadrature output (denoted as “-90°), and a respective in-phase output (denoted as “0°”). In an embodiment, the respective isolation port (ISO) in the first input hybrid coupler 56 and the respective isolation port (ISO) in the second input hybrid coupler 58 are both coupled to an isolation resistor R_{ISO}.

The first input hybrid coupler 56 receives the amplified inverting driver stage signal 60B via the respective input port (IN). Accordingly, the first input hybrid coupler 56 is configured to generate a respective non-inverting component 28A (e.g., -180°) in the first differential signal 28 via the respective in-phase output (0°) and a respective inverting component 30A (e.g., -270°) in the second differential signal 30 via the respective quadrature-phase output (-90°).

The second input hybrid coupler 58 receives the amplified non-inverting driver stage signal 60A via the respective input port (IN). Accordingly, the second input hybrid coupler 58 is configured to generate a respective non-inverting component 28B (e.g., 0°) in the first differential signal 28 via the respective in-phase output (0°) and a respective inverting component 30B (e.g., -90°) in the second differential signal 30 via the respective quadrature output (-90°).

Herein, a source signal, such as the non-inverting driver stage signal 60A and the inverting driver stage signal 60B, can include a non-inverting component and an inverting component. In context of the present disclosure, the non-inverting component has an identical phase (e.g., 0° phase offset) as the source signal, whereas the inverting component has a quadrature phase offset (e.g., ±90° phase offset) relative to the source signal. As an example, the non-inverting component 28A has an identical phase (-180°) as the inverting driver stage signal 60B (-180°) and the non-inverting component 28B has an identical phase (0°) as the non-inverting driver stage signal 60A (0°). In contrast, the inverting component 30A has a quadrature phase offset (-270°) relative to the inverting driver stage signal 60B (-180°) and the inverting component 30B has a quadrature phase offset (-90°) relative to the non-inverting driver stage signal 60A (0°).

By employing the first input hybrid coupler 56 and the second input hybrid coupler 58, it is possible to eliminate the balanced-to-unbalanced transformer 42, the quadrature unbalanced-to-balanced transformer 46, and the in-phase unbalanced-to-balanced transformer 48 from the conventional driver stage 36. As such, the driver stage 14 can be built on a significantly smaller die compared to the conventional driver stage 36. As a result, it is possible to reduce the overall footprint of the multi-stage differential power amplifier circuit 12.

The driver stage 14A is coupled to the first output stage differential power amplifier 22 and the second output stage differential power amplifier 24. As described above in FIG. 2, the first output stage differential power amplifier 22 is always activated to amplify the first differential signal 28, whereas the second output stage differential power amplifier 24 is only activated as needed to amplify the second differential signal 30.

In an embodiment, the output circuit 26 includes a first balanced-to-unbalanced transformer 62, a second balanced-to-unbalanced transformer 64, and an output hybrid coupler 66. The first balanced-to-unbalanced transformer 62 is configured to convert the amplified first differential signal 28 into a quadrature output stage signal 68Q and the second balanced-to-unbalanced transformer is configured to convert the amplified second differential signal 30 into an in-phase output stage signal 68I.

The output hybrid coupler 66 includes a respective in-phase input (denoted as “0°”), a respective quadrature input (denoted as “-90°), a respective isolation port (denoted as “ISO”), and a respective output port (denoted as “OUT”). In an embodiment, the isolation port (ISO) may be terminated by an isolation capacitor C_{ISO}. The output hybrid coupler 66 receives the in-phase output stage signal 68I and the quadrature output stage signal 68Q via the in- phase input (0°) and the quadrature input (-90°), respectively. Accordingly, the output hybrid coupler 66 can combine the in-phase output stage signal 68I and the quadrature output stage signal 68Q to thereby output the amplified RF signal 20 via the output port (OUT).

FIG. 4B is a schematic diagram providing an exemplary illustration of a driver stage 14B, which can replace the driver stage 14 in FIG. 1 and configured according to an embodiment to occupy a smaller footprint compared to the conventional driver stage 36 in FIG. 3. Common elements between FIGS. 4A and 4B are shown therein with common element numbers and will not be re-described herein.

In an embodiment, the respective isolation port (ISO) in the first input hybrid coupler 56 and the respective isolation port (ISO) in the second input hybrid coupler 58 are each coupled to the ground (GND) via a respective isolation resistor R_{ISO}.

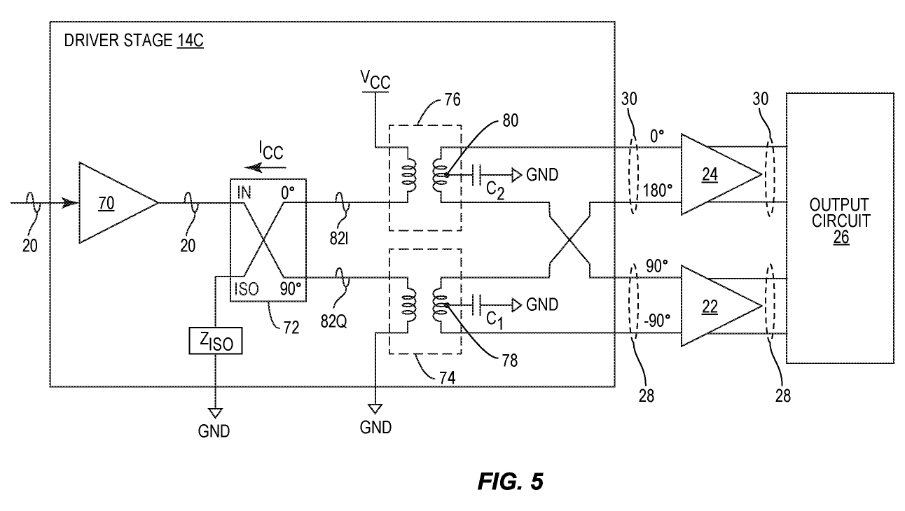

FIG. 5 is a schematic diagram providing an exemplary illustration of a driver stage 14C, which can replace the driver stage 14 in FIG. 1 and configured according to another embodiment to reduce the footprint of the conventional driver stage 36 in FIG. 3. Common elements between FIGS. 1, 4A, 4B and 5 are shown therein with common element numbers and will not be re-described herein.

Herein, the driver stage 14C includes a driver stage power amplifier 70, an input hybrid coupler 72, a first unbalanced-to-balanced transformer 74, and a second unbalanced-to-balanced transformer 76. The input hybrid coupler 72 includes an input port (denoted as “IN”) that is coupled to the driver stage power amplifier 70 and an isolation port (denoted as “ISO”) that is terminated by an isolation impedance Z_{ISO}. The input hybrid coupler 72 also includes an in-phase output (denoted as “0°”) that is coupled to the second unbalanced-to-balanced transformer 76 and a quadrature output (denoted as “90°”) that is coupled to the first unbalanced-to-balanced transformer 74.

The driver stage 14C also includes a pair of capacitors C₁, C₂. The capacitor C₁ is coupled between a first center tap point 78 in the first unbalanced-

to-balanced transformer 74 and the GND, whereas the capacitor C₂ is coupled between a second center tap point 80 in the second unbalanced-to-balanced transformer 76 and the GND. Moreover, the second unbalanced-to-balanced transformer 76 is configured to receive the supply voltage V_{CC}, thus passing a supply current I_{CC} between the in-phase output (0°) and the input port (IN).

Herein, the driver stage power amplifier 70 is configured to amplify the RF signal 20 and provide the amplified RF signal 20 to the input port (IN). The input hybrid coupler 72 is configured to convert the amplified RF signal 20 into an amplified in-phase signal 82I and an amplified quadrature signal 82Q. The first unbalanced-to-balanced transformer 74 is configured to generate the first differential signal 28 from the amplified quadrature signal 82Q, and the second unbalanced-to-balanced transformer 76 is configured to generate the second differential signal 30 from the amplified in-phase signal 82I.

Herein, the first output stage differential power amplifier 22, the second output stage differential power amplifier 24, and the output circuit 26 are identical to the first output stage differential power amplifier 22, the second output stage differential power amplifier 24, and the output circuit 26 previously described in FIG. 4. As such, the first output stage differential power amplifier 22, the second output stage differential power amplifier 24, and the output circuit 26 will operate exactly like the first output stage differential power amplifier 22, the second output stage differential power amplifier 24, and the output circuit 26 in FIG. 4.

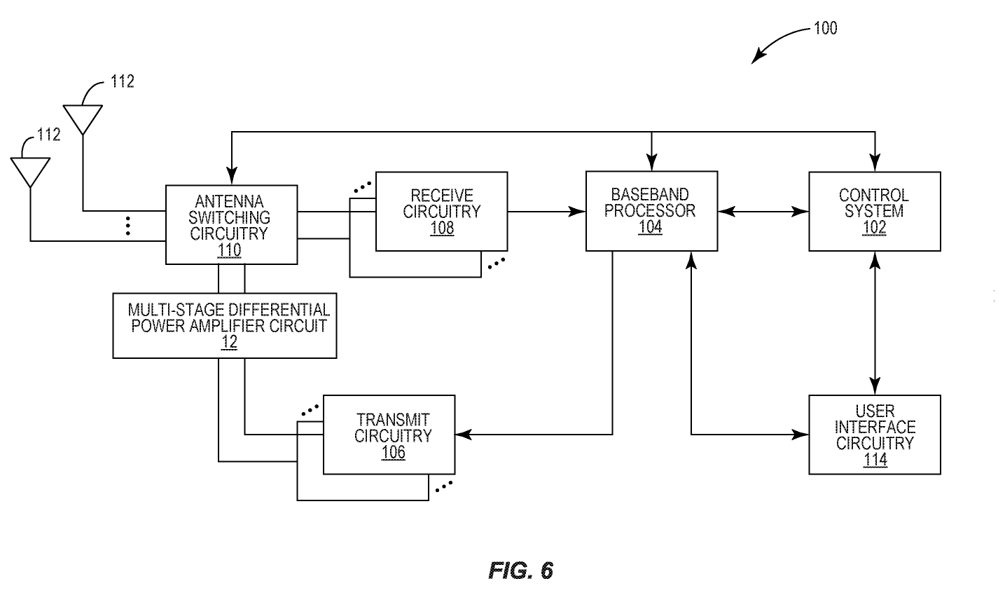

The power management circuit 10 of FIG. 1 can be provided in a communication device to support the embodiments described above. In this regard, FIG. 6 is a schematic diagram of an exemplary communication device 100 wherein the power management circuit 10 of FIG. 1 can be provided.

Herein, the communication device 100 can be any type of communication devices, such as mobile terminals, smart watches, tablets, computers, navigation devices, access points, base stations (e.g., eNB, gNB, etc.), and like wireless communication devices that support wireless communications, such as cellular, wireless local area network (WLAN), Ultra- wideband (UWB), Bluetooth, and near-field communications. The communication device 100 will generally include a control system 102, a baseband processor 104, transmit circuitry 106, receive circuitry 108, antenna switching circuitry 110, multiple antennas 112, and user interface circuitry 114. In a non-limiting example, the control system 102 can be a field-programmable gate array (FPGA), as an example. In this regard, the control system 102 can include at least a microprocessor, an embedded memory circuit, and a communication bus interface. The receive circuitry 108 receives radio frequency signals via the antennas 112 and through the antenna switching circuitry 110 from one or more base stations. A low-noise amplifier and a filter cooperate to amplify and remove broadband interference from the received signal for processing. Downconversion and digitization circuitry (not shown) will then downconvert the filtered, received signal to an intermediate or baseband frequency signal, which is then digitized into one or more digital streams using analog-to-digital converters (ADCs).

The baseband processor 104 processes the digitized received signal to extract the information or data bits conveyed in the received signal. This processing typically comprises demodulation, decoding, and error correction operations, as will be discussed in greater detail below. The baseband processor 104 is generally implemented in one or more digital signal processors (DSPs) and application-specific integrated circuits (ASICs).

For transmission, the baseband processor 104 receives digitized data, which may represent voice, data, or control information, from the control system 102, which it encodes for transmission. The encoded data is output to the transmit circuitry 106, where a digital-to-analog converter (DAC) converts the digitally encoded data into an analog signal and a modulator modulates the analog signal onto a carrier signal that is at a desired transmit frequency or frequencies. A power amplifier will amplify the modulated carrier signal to a level appropriate for transmission and deliver the modulated carrier signal to the antennas 112 through the antenna switching circuitry 110. The multiple antennas 112 and the replicated transmit 106 and receive circuitry 108 may provide spatial diversity. Modulation and processing details will be understood by those skilled in the art.

In an embodiment, the transmit circuitry 106 and the receive circuitry 108 can function as the transceiver circuit 16 in FIG. 1. Accordingly, the multi-stage differential power amplifier circuit 12 can be provided between the transmit circuitry 106 and the antenna switching circuitry 110.

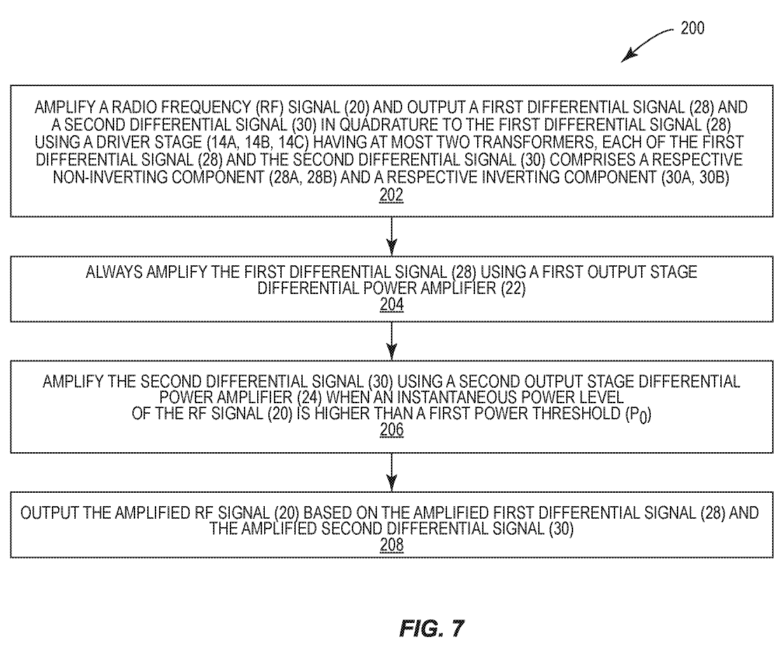

In an embodiment, it is possible to reduce the footprint of the driver stage 14 in the power management circuit 10 of FIG. 1 in accordance with a process. In this regard, FIG. 7 is a flowchart of an exemplary process 200 for reducing the footprint of the driver stage 14 in the multi-stage differential power amplifier circuit 12 in FIG. 1.

Herein, the process 200 includes amplifying the RF signal 20 and outputting the first differential signal 28 and the second differential signal 30 in quadrature to the first differential signal 28 using the driver stage 14A, 14B, or 14C that includes at most two transformers (step 202). Each of the first differential signal 28 and the second differential signal 30 includes a respective non-inverting component 28A or 28B and a respective inverting component 30A or 30B. The process 200 also includes always amplifying the first differential signal 28 using the first output stage differential power amplifier 22 (step 204). The process 200 also includes amplifying the second differential signal 30 using the second output stage differential power amplifier 24 when the instantaneous power level of the RF signal 20 is higher than the first power threshold P₀ (step 206). The process 200 also includes outputting the amplified RF signal 20 based on the amplified first differential signal 28 and the amplified second differential signal 30 (step 208).

Those skilled in the art will recognize improvements and modifications to the preferred embodiments of the present disclosure. All such improvements and modifications are considered within the scope of the concepts disclosed herein and the claims that follow.

What is claimed is:

1. A multi-stage differential power amplifier circuit comprising:
a driver stage comprising at most two transformers and configured to amplify a radio frequency (RF) signal and output a first differential signal and a second differential signal in quadrature to the first differential signal, each of the first differential signal and the second differential signal comprises a respective non-inverting component and a respective inverting component;
a first output stage differential power amplifier always activated to further amplify the first differential signal based on a supply voltage;
a second output stage differential power amplifier activated only when an instantaneous power level of the RF signal is higher than a first power threshold to further amplify the second differential signal based on the supply voltage; and
an output circuit configured to output the amplified RF signal based on the amplified first differential signal and the amplified second differential signal.

2. The multi-stage differential power amplifier circuit of claim 1, wherein the output circuit is further configured to:
modulate a load impedance at an output of the first output stage differential power amplifier when the instantaneous power level of the RF signal is higher than the first power threshold and lower than or equal to a second power threshold that is higher than the first power threshold; and
present a fixed load impedance at the output of the first output stage differential power amplifier when the instantaneous power level of the RF signal is lower than or equal to the first power threshold or higher than the second power threshold.

3. The multi-stage differential power amplifier circuit of claim 1, wherein the driver stage comprises:
an unbalanced-to-balanced transformer configured to convert the RF signal into a driver stage differential signal comprising a non-inverting driver stage signal and an inverting driver stage signal;
a driver stage differential power amplifier configured to amplify the non-inverting driver stage signal and the inverting driver stage signal in the driver stage differential signal;
a first input hybrid coupler configured to generate the respective inverting component in the first differential signal and the second differential signal based on the inverting driver stage signal in the amplified driver stage differential signal; and
a second input hybrid coupler configured to generate the respective non-inverting component in the first differential signal and the second differential signal based on the inverting driver stage signal in the amplified driver stage differential signal.

4. The multi-stage differential power amplifier circuit of claim 3, wherein the output circuit comprises:
a first balanced-to-unbalanced transformer configured to convert the amplified first differential signal into a quadrature output stage signal;
a second balanced-to-unbalanced transformer configured to convert the amplified second differential signal into an in-phase output stage signal; and
an output hybrid coupler configured to combine the in-phase output stage signal and the quadrature output stage signal to thereby output the amplified RF signal.

5. The multi-stage differential power amplifier circuit of claim 1, wherein the driver stage comprises:
a driver stage power amplifier configured to amplify the RF signal;
an input hybrid coupler configured to convert the amplified RF signal into an amplified in-phase signal and an amplified quadrature signal;
a first unbalanced-to-balanced transformer configured to generate the first differential signal from the amplified quadrature signal; and
a second unbalanced-to-balanced transformer configured to generate the second differential signal from the amplified in-phase signal.

6. The multi-stage differential power amplifier circuit of claim 5, wherein the output circuit comprises:
a first balanced-to-unbalanced transformer configured to convert the amplified first differential signal into a quadrature output stage signal;
a second balanced-to-unbalanced transformer configured to convert the amplified second differential signal into an in-phase output stage signal; and
an output hybrid coupler configured to combine the in-phase output stage signal and the quadrature output stage signal to thereby output the amplified RF signal.

7. A wireless device comprising a multi-stage differential power amplifier circuit, the multi-stage differential power amplifier circuit comprises:
a driver stage comprising at most two transformers and configured to amplify a radio frequency (RF) signal and output a first differential signal and a second differential signal in quadrature to the first differential signal, each of the first differential signal and the second differential signal comprises a respective in-phase signal and a respective out-of-phase signal;
a first output stage differential power amplifier always activated to further amplify the first differential signal based on a supply voltage;
a second output stage differential power amplifier activated only when an instantaneous power level of the RF signal is higher than a first power threshold to further amplify the second differential signal based on the supply voltage; and
an output circuit configured to output the amplified RF signal based on the amplified first differential signal and the amplified second differential signal.

8. The wireless device of claim 7, further comprising:
a transceiver circuit configured to generate the RF signal and a target voltage tracking a time-variant input power of the RF signal; and
a power management integrated circuit (PMIC) configured to generate the supply voltage based on the target voltage.

9. The wireless device of claim 7, wherein the output circuit is further configured to:
modulate a load impedance at an output of the first output stage differential power amplifier when the instantaneous power level of the RF signal is higher than or equal to the first power threshold; and
present a fixed load impedance at the output of the first output stage differential power amplifier when the instantaneous power level of the RF signal is lower than the first power threshold or higher than or equal to a second power threshold higher than the first power threshold.

10. The wireless device of claim 7, wherein the driver stage comprises:
an unbalanced-to-balanced transformer configured to convert the RF signal into a driver stage differential signal comprising a non-inverting driver stage signal and an inverting driver stage signal;
a driver stage differential power amplifier configured to amplify the non-inverting driver stage signal and the inverting driver stage signal in the driver stage differential signal;
a first input hybrid coupler configured to generate the respective inverting component in the first differential signal and the second differential signal based on the non-inverting driver stage signal in the amplified driver stage differential signal; and
a second input hybrid coupler configured to generate the respective non-inverting component in the first differential signal and the second differential signal based on the inverting driver stage signal in the amplified driver stage differential signal.

11. The wireless device of claim 10, wherein the output circuit comprises:
a first balanced-to-unbalanced transformer configured to convert the amplified first differential signal into a quadrature output stage signal;
a second balanced-to-unbalanced transformer configured to convert the amplified second differential signal into an in-phase output stage signal; and
an output hybrid coupler configured to combine the in-phase output stage signal and the quadrature output stage signal to thereby output the amplified RF signal.

12. The wireless device of claim 7, wherein the driver stage comprises:
a driver stage power amplifier configured to amplify the RF signal;
an input hybrid coupler configured to convert the amplified RF signal into an amplified in-phase signal and an amplified quadrature signal;
a first unbalanced-to-balanced transformer configured to generate the first differential signal from the amplified quadrature signal; and
a second unbalanced-to-balanced transformer configured to generate the second differential signal from the amplified in-phase signal.

13. The wireless device of claim 12, wherein the output circuit comprises:
a first balanced-to-unbalanced transformer configured to convert the amplified first differential signal into a quadrature output stage signal;
a second balanced-to-unbalanced transformer configured to convert the amplified second differential signal into an in-phase output stage signal; and
an output hybrid coupler configured to combine the in-phase output stage signal and the quadrature output stage signal to thereby output the amplified RF signal.

14. A method for reducing an input footprint of a multi-stage differential power amplifier circuit comprising:
amplifying a radio frequency (RF) signal and outputting a first differential signal and a second differential signal in quadrature to the first differential signal using a driver stage comprising at most two transformers, each of the first differential signal and the second differential signal comprises a respective non-inverting component and a respective inverting component;
always amplifying the first differential signal using a first output stage differential power amplifier;
amplifying the second differential signal using a second output stage differential power amplifier when an instantaneous power level of the RF signal is higher than a first power threshold; and
outputting the amplified RF signal based on the amplified first differential signal and the amplified second differential signal.

15. The method of claim 14, further comprising:
modulating a load impedance when the instantaneous power level of the RF signal is higher than or equal to the first power threshold; and
presenting a fixed load impedance when the instantaneous power level of the RF signal is lower than the first power threshold or higher than or equal to a second power threshold higher than the first power threshold.

16. The method of claim 14, further comprising:
converting the RF signal into a driver stage differential signal comprising a non-inverting driver stage signal and an inverting driver stage signal;
amplifying the non-inverting driver stage signal and the inverting driver stage signal in the driver stage differential signal;
generating the respective inverting component in the first differential signal and the second differential signal based on the non-inverting driver stage signal in the amplified driver stage differential signal; and
generating the respective non-inverting component in the first differential signal and the second differential signal based on the inverting driver stage signal in the amplified driver stage differential signal.

17. The method of claim 16, further comprising:
converting the amplified first differential signal into a quadrature output stage signal;
converting the amplified second differential signal into an in-phase output stage signal; and
combining the in-phase output stage signal and the quadrature output stage signal to thereby output the amplified RF signal.

18. The method of claim 14, further comprising:
amplifying the RF signal;
converting the amplified RF signal into an amplified in-phase signal and an amplified quadrature signal;
generating the first differential signal from the amplified quadrature signal; and
generating the second differential signal from the amplified in-phase signal.

19. The method of claim 18, further comprising:
converting the amplified first differential signal into a quadrature output stage signal;
converting the amplified second differential signal into an in-phase output stage signal; and
combining the in-phase output stage signal and the quadrature output stage signal to thereby output the amplified RF signal.
